(19) United States
(12) Patent Application Publication
(10) Pub. No.: US 2019/0372249 A1
(43) Pub. Date: Dec. 5, 2019

(54) CONNECTOR USING PRINTED CIRCUIT BOARD

(71) Applicant: 3M INNOVATIVE PROPERTIES COMPANY, St. Paul, MN (US)

(72) Inventors: YunLong Qiao, Singapore (SG); Saujit Bandhu, Singapore (SG); Kok Hoe Lee, Singapore (SG); Chin Hua Lim, Singapore (SG); Rao L. Vittapalli, Singapore (SG)

(21) Appl. No.: 16/462,731

(22) PCT Filed: Dec. 18, 2017
(86) PCT No.: PCT/IB2017/058058

§ 371 Date: May 21, 2019

Related U.S. Application Data
(60) Provisional application No. 62/437,749, filed on Dec. 22, 2016.

(51) Int. Cl. H01R 12/70; H05K 1/11; H01R 13/50

(52) U.S. Cl. CPC H01R 12/70; H05K 1/117; H05K 1/119; H05K 2201/2018; H05K 2201/09172; H05K 2201/09163; H01R 13/50

(57) ABSTRACT

An elongated connector includes a circuit board and a connector frame removably attached to the circuit board. First contact pads and second contact pads are integrally formed on a top surface and near a front edge of the circuit board. A first opening is disposed at the front edge of the circuit board on a side of a first region. A second opening is disposed at the front edge of the circuit board on an opposite side of a second region. The elongated base is disposed on the top surface of the circuit board behind the first and second regions. When the connector mates with a mating connector, the first and second regions of the circuit board are inserted in the mating connector and each contact pad in the pluralities of first and second contact pads makes contact with a corresponding contact of the mating connector.

### TECHNICAL FIELD

This application relates to electrical connectors and electrical connector assemblies.

### BACKGROUND

Electrical cables facilitate transmission of electrical signals between devices. Cable connectors can be designed to provide interconnection between devices having a particular type of communications protocol, such as serially attached small computer interface system (SAS) and peripheral component interconnect express (PCIe). In view of the need for high speed interconnection between computers and peripheral devices, a continuing need exists for electrical cables that are capable of transmitting high speed signals, are mechanically robust, cost-effective, and can be used in a variety of applications.

### BRIEF SUMMARY

Some embodiments are directed to an elongated electrical connector for mating with a mating connector along a mating direction. The elongated electrical connector includes a circuit board and a connector frame removably attached to the circuit board. A plurality of first contact pads is integrally formed in a first region on a top surface and near a front edge of the circuit board. A plurality of second contact pads is integrally formed in a second region on the top surface and near the front edge of the circuit board. The first and second regions define a third region therebetween on the top surface of the circuit board. The third region has no contact pads therein. A first opening is disposed at the front edge of the circuit board on a side of the first region. A second opening is disposed at the front edge of the circuit board on an opposite side of the second region.

The connector frame has an elongated base that extends along a longitudinal direction perpendicular to the mating direction. The elongated base is disposed on the top surface of the circuit board behind the first and second regions. First and second endwalls of the connector frame extend forwardly along the mating direction from respective opposite first and second longitudinal ends of the base. The first and second endwalls are at least partially disposed in the respective first and second openings. Spaced apart first and second middle walls extend forwardly along the mating direction from the base between the first and second endwalls. At least one of the first and second middle walls is disposed in the third region.

The circuit board extends rearwardly along the mating direction beyond the base and extends sidewardly along the longitudinal direction beyond the first and second endwalls. When the connector mates with a mating connector, the first and second regions of the circuit board are inserted in the mating connector and each contact pad in the pluralities of first and second contact pads makes contact with a corresponding contact of the mating connector.

In some embodiments, each of the first and second middle walls is disposed in the third region of the circuit board, and the third region defines a third opening at the front edge of the circuit board between the first and second middle walls.

According to some embodiments, the circuit board further includes a plurality of third contact pads integrally formed in a fourth region on the top surface and near the front edge of the circuit board. The second region is disposed between the third and fourth regions. The fourth and second regions define a fifth region therebetween on the top surface of the circuit board and having no contact pads therein. The first middle wall is disposed in the third region of the circuit board and the second middle wall is disposed in the fifth region of the circuit board. The third region defines a third opening at the front edge of the circuit board adjacent to the first middle wall.

### BRIEF DESCRIPTION OF THE DRAWINGS

FIG. 1A shows an assembled connector in accordance with some embodiments;

FIG. 1B is an exploded view of the connector of FIG. 1A;

FIG. 2A shows an assembled connector in accordance with some embodiments;

FIG. 2B is an exploded view of the connector of FIG. 2A;

FIG. 3A shows an assembled connector in accordance with some embodiments; and

FIG. 3B is an exploded view of the connector of FIG. 3A;

The figures are not necessarily to scale. Like numbers used in the figures refer to like components. However, it will be understood that the use of a number to refer to a component in a given figure is not intended to limit the component in another figure labeled with the same number.

### DESCRIPTION OF ILLUSTRATIVE EMBODIMENTS

Electrical connectors are used in many applications such as to interconnect hard disk drives or solid state drives to the motherboard of a computer. In some previous approaches, the plug connector with electrical interconnects is soldered onto pads of a printed circuit board (PCB). As the pin count increases, the complexity of these approaches leads to challenges in maintaining high quality of electrical contacts and high-speed communications through the connector.

The embodiments described herein are directed to connectors that use a printed circuit board itself to serve as the tongue interface of the plug connector. The connectors disclosed herein are useful for serial AT attachment (SATA) connectors, serial attachment small computer systems interface (SAS) connectors, and peripheral component internet express (PCIe) SAS right angle plug connectors, among other connector types.

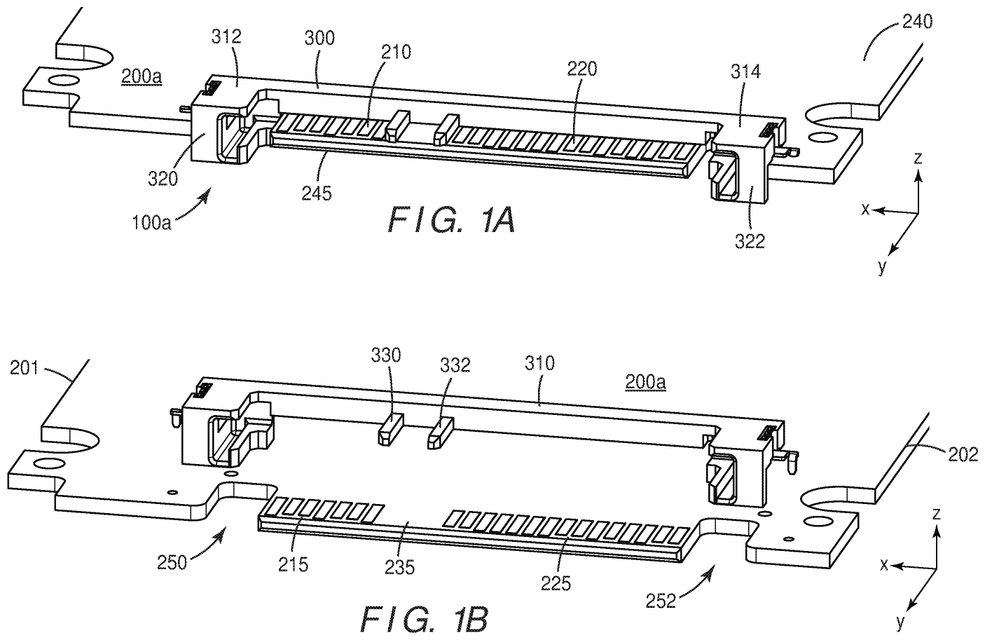

FIG. 1A shows an elongated electrical connector 100a in accordance with some embodiments. FIG. 1B is an exploded view showing the components of the electrical connector 100a. The elongated electrical connector 100a is configured for mating with a mating connector (not shown in FIGS. 1A and 1B) along a mating direction, y.

The connector 100a includes a circuit board 200a and a connector frame 300 removably attached to the circuit board 200a. A plurality of first contact pads 210 are integrally formed in a first region 215 on a top surface 240 and near a front edge 245 of the circuit board 200a. A plurality of second contact pads 220 are integrally formed in a second region 225 on the top surface 240 and near the front edge 245 of the circuit board 200a. According to various implementations, the pluralities of first 210 and second 220 contact pads may be integrally formed by a photolithography process and/or may be formed by a printing process.

The first 215 and second 225 regions define a third region 235 therebetween on the top surface 240 of the circuit board 200a. As depicted in FIGS. 1A and 1B, the third region 235 has no contact pads therein. The circuit board 200a has a first opening 250 at the front edge 245 of the circuit board 200a on a side of the first region 215. The first opening 250 is located between a first side 201 of the circuit board 200a and the first region 215. A second opening 252 of the circuit board 200a is located at the front edge 245 of the circuit board 200a on an opposite side of the second region 225. The second opening 252 is located between the second side 202 of the circuit board 200a and the second region 225.

The connector frame 300 includes an elongated base 310 that extends along a longitudinal direction, x, perpendicular to the mating connector direction, y. The elongated base 310 is disposed on the top surface 240 of the circuit board 200a behind the first 215 and second 225 regions. First 320 and second 322 endwalls of the connector frame 300 extend forwardly along the mating direction, y, from respective opposite first 312 and second 314 longitudinal ends of the base 310. The first 320 and second 322 endwalls are at least partially disposed in the respective first 250 and second 252 openings. Spaced apart first 330 and second 332 middle walls extend forwardly along the mating direction from the base 310 between the first 320 and second 322 endwalls. At least one of the first 330 and second 332 middle walls is disposed in the third region 325. Each of the first 330 and second 332 middle walls may be disposed in the third region 235 of the circuit board 200a.

As depicted in FIGS. 1A and 1B, the circuit board 200a extends rearwardly along the mating axis, y, beyond the elongated base 310 and extends sidewardly along the longitudinal axis, x, beyond the first 320 and second 322 endwalls. When the connector 100a mates with a mating connector (not shown in FIGS. 1A and 1B), the first 215 and second 225 regions of the circuit board 200a are inserted in the mating connector and each contact pad in the pluralities of first 210 and second 220 contact pads makes contact with a corresponding contact of the mating connector.

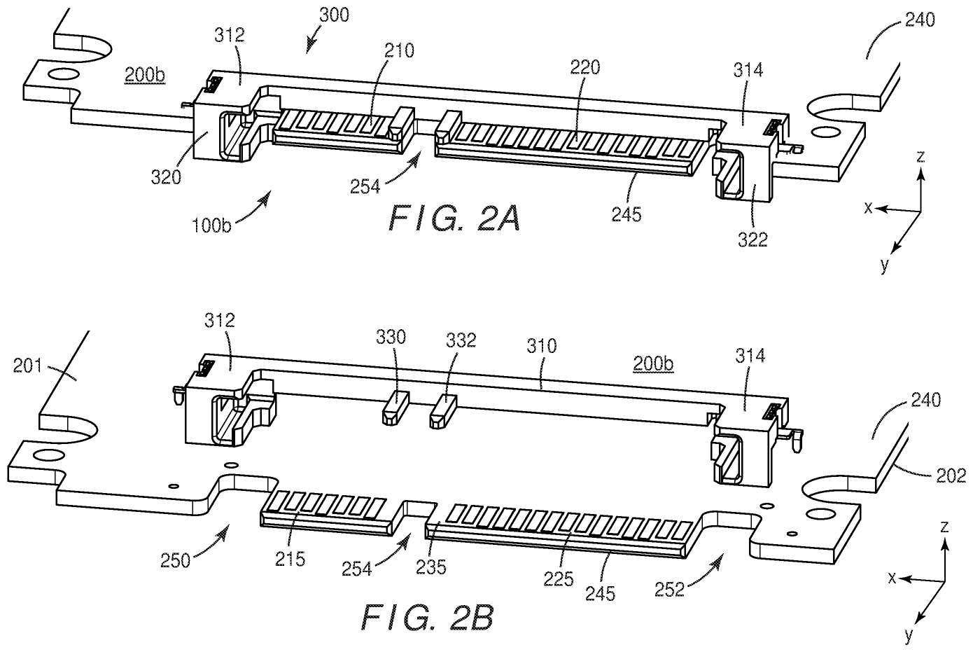

FIGS. 2A and 2B illustrate a connector 100b that is similar in many respects to the connector 100a shown in FIGS. 1A and 1B where like numbers used refer to like components. FIG. 2A shows the assembled electrical connector 100b and FIG. 2B shows an exploded view of components of the electrical connector 100b. The elongated electrical connector 100b is configured for mating with a mating connector (not shown in FIGS. 2A and 2B) along a mating direction, y.

The connector 100b includes a circuit board 200b and a connector frame 300 removably attached to the circuit board 200b. A plurality of first contact pads 210 are integrally formed in a first region 215 on a top surface 240 and near a front edge 245 of the circuit board 200b. A plurality of second contact pads 220 are integrally formed in a second region 225 on the top surface 240 and near the front edge 245 of the circuit board 200b. According to various implementations, the pluralities of first 210 and second 220 contact pads may be integrally formed by a photolithography process and/or may be formed by a printing process.

The first 215 and second 225 regions define a third region 235 therebetween on the top surface 240.

The circuit board 200b has a first opening 250 at the front edge 245 of the circuit board 200b on a side of the first region 215. The first opening 250 is located between a first side 201 of the circuit board 200b and the first region 215. A second opening 252 of the circuit board 200b is located at the front edge 245 of the circuit board 200b on an opposite side of the second region 225. The second opening 252 is located between the second side 202 of the circuit board 200 and the second region 225. The third region 235 defines a third opening 254 at the front edge of the circuit board 200b. The third opening is disposed between the first 330 and second 332 middle walls of the connector frame 300.

The connector frame 300 includes an elongated base 310 that extends along a longitudinal direction, x, perpendicular to the mating connector direction, y. The elongated base 310 is disposed on the top surface 240 of the circuit board 200 behind the first 215 and second 225 regions. First 320 and second 322 endwalls of the connector frame 300 extend forwardly along the mating direction, y, from respective opposite first 312 and second 314 longitudinal ends of the base 310. The first 320 and second 322 endwalls are at least partially disposed in the respective first 250 and second 252 openings. Spaced apart first 330 and second 332 middle walls extend forwardly along the mating direction from the base 310 between the first 320 and second 322 endwalls. At least one of the first 330 and second 332 middle walls is disposed in the third region 235. Each of the first 330 and second 332 middle walls may be disposed in the third region 235 of the circuit board 200b as shown in FIGS. 2A and 2B.

As depicted in FIGS. 2A and 2B, the circuit board 200b extends rearwardly along the mating axis, y, beyond the elongated base 310 and extends sidewardly along the longitudinal axis, x, beyond the first 320 and second 322 endwalls. When the connector 100b mates with a mating connector (not shown in FIGS. 2A and 2B), the first 215 and second 225 regions of the circuit board 200b are inserted in the mating connector and each contact pad in the pluralities of first 210 and second 220 contact pads makes contact with a corresponding contact of the mating connector.

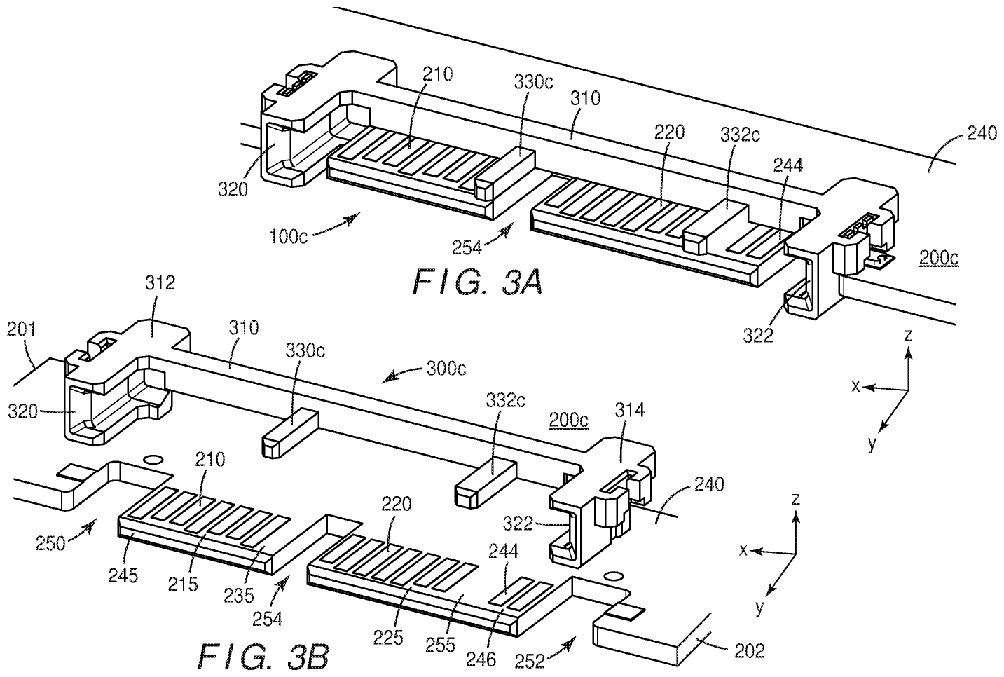

FIGS. 3A and 3B illustrate a connector 100c that is similar in many respects to the connector 100a shown in FIGS. 1A and 1B and the connector 100b shown in FIGS. 2A and 2B where like numbers used refer to like components. FIG. 3A shows the assembled electrical connector 100c and FIG. 3B shows an exploded view of the components of the electrical connector 100c. The elongated electrical connector 100c is configured for mating with a mating connector (not shown in FIGS. 3A and 3B) along a mating direction, y.

The connector 100c includes a circuit board 200c and a connector frame 300c removably attached to the circuit board 200c. A plurality of first contact pads 210 are integrally formed in a first region 215 on a top surface 240 and near a front edge 245 of the circuit board 200c. A plurality of second contact pads 220 are integrally formed in a second region 225 on the top surface 240 and near the front edge 245 of the circuit board 200c. A plurality of third contact pads 244 is integrally formed in a fourth region 246 on the top surface 240 and near the front edge 245 of the circuit board 200c. According to various implementations, the pluralities of first 210, second 220, and third 244 contact pads may be integrally formed by a photolithography process and/or may be formed by a printing process.

The first 215 and second 225 regions define a third region 235 therebetween on the top surface 240 and near the front edge 245 of the circuit board 200c. The second region 225 is disposed between the third region 235 and the fourth 246 region. The fourth 246 and second 225 regions define a fifth region 255 therebetween on the top surface 240 and near the front edge 245. The fifth region 255 has no contact pads therein. The first middle wall 330c is disposed in the third region 235 of the circuit board 200c. The second middle wall 332c is disposed in the fifth region 255 of the circuit board 200c.

The circuit board 200b has a first opening 250 at the front edge 245 of the circuit board 200c on a side of the first region 215. The first opening 250 is located between a first side 201 of the circuit board 200c and the first region 215. A second opening 252 of the circuit board 200c is located at the front edge 245 of the circuit board 200b on an opposite side of the fourth region 246. The second opening 252 is located between the second side 202 of the circuit board 200 and the fourth region 246. The third region 235 defines a third opening 254 at the front edge of the circuit board 200b. The third opening 254 is disposed in the third region 235 between the first region 215 and the second region 225.

The connector frame 300c includes an elongated base 310 that extends along a longitudinal direction, x, perpendicular to the mating connector direction, y. The elongated base 310 is disposed on the top surface 240 of the circuit board 200c behind the first 215 and second 225 regions. First 320 and second 322 endwalls of the connector frame 300c extend forwardly along the mating direction, y, from respective opposite first 312 and second 314 longitudinal ends of the base 310. The first 320 and second 322 endwalls are at least partially disposed in the respective first 250 and second 252 openings. Spaced apart first 330c and second 332c middle walls extend forwardly along the mating direction from the base 310 between the first 320 and second 322 endwalls. The first 330c middle wall is disposed on the third region 235. The second middle wall 332c is disposed in the fifth region 255.

As depicted in FIGS. 3A and 3B, the circuit board 200c extends rearwardly along the mating axis, y beyond the elongated base 310 and extends sidewardly along the longitudinal axis, x, beyond the first 320 and second 322 endwalls. When the connector 100c mates with a mating connector (not shown in FIGS. 3A and 3B), the first 215, second 225, and fourth 246 regions of the circuit board 200c are inserted in the mating connector and each contact pad in the pluralities of first 210, second 220, and third 244 contact pads makes contact with a corresponding contact of the mating connector.

Embodiments disclosed herein include:

### Embodiment 1

An elongated electrical connector for mating with a mating connector along a mating direction, the connector comprising:

a circuit board comprising:

a plurality of first contact pads integrally formed in a first region on a top surface and near a front edge of the circuit board;

a plurality of second contact pads integrally formed in a second region on the top surface and near the front edge of the circuit board, the first and second regions defining a third region therebetween on the top surface having no contact pads therein;

a first opening at the front edge of the circuit board on a side of the first region;

a second opening at the front edge of the circuit board on an opposite side of the second region; and

a connector frame removably attached to the circuit board and comprising:
an elongated base extending along a longitudinal direction (x) perpendicular to the mating direction and disposed on the top surface of the circuit board behind the first and second regions;
first and second endwalls extending forwardly along the mating direction from respective opposite first and second longitudinal ends of the base, the first and second endwalls at least partially disposed in the respective first and second openings; and
spaced apart first and second middle walls extending forwardly along the mating direction from the base between the first and second endwalls, at least one of the first and second middle walls disposed in the third region, wherein:
the circuit board extends rearwardly along the mating direction beyond the base,
the circuit board extends sidewardly along the longitudinal direction beyond the first and second endwalls; and
when the connector mates with a mating connector, the first and second regions of the circuit board are inserted in the mating connector and each contact pad in the pluralities of first and second contact pads makes contact with a corresponding contact of the mating connector.

### Embodiment 2

The elongated electrical connector of embodiment 1, wherein the pluralities of first and second contact pads are integrally formed by a photolithography process.

### Embodiment 3

The elongated electrical connector of embodiment 1, wherein the pluralities of first and second contact pads are integrally formed by a printing process.

### Embodiment 4

The elongated electrical connector of any of embodiments 1 through 3, wherein each of the first and second middle walls is disposed in the third region of the circuit board.

### Embodiment 5

The elongated electrical connector of any of embodiments 1 through 3, wherein each of the first and second middle walls is disposed in the third region of the circuit board, and the third region defines a third opening at the front edge of the circuit board between the first and second middle walls.

### Embodiment 6

The elongated electrical connector of embodiment 1, wherein the circuit board further comprises a plurality of third contact pads integrally formed in a fourth region on the top surface and near the front edge of the circuit board, the second region disposed between the third and fourth regions, the fourth and second regions defining a fifth region therebetween on the top surface having no contact pads therein, and wherein the first middle wall is disposed in the third region of the circuit board and the second middle wall is disposed in the fifth region of the circuit board, and wherein the third region defines a third opening at the front edge of the circuit board adjacent to the first middle wall.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

Various modifications and alterations of these embodiments will be apparent to those skilled in the art and it should be understood that this scope of this disclosure is not limited to the illustrative embodiments set forth herein. For example, the reader should assume that features of one disclosed embodiment can also be applied to all other disclosed embodiments unless otherwise indicated.

1. An elongated electrical connector for mating with a mating connector along a mating direction, the connector comprising:
a circuit board comprising:
a plurality of first contact pads integrally formed in a first region on a top surface and near a front edge of the circuit board;
a plurality of second contact pads integrally formed in a second region on the top surface and near the front edge of the circuit board, the first and second regions defining a third region therebetween on the top surface having no contact pads therein;
a first opening at the front edge of the circuit board on a side of the first region;
a second opening at the front edge of the circuit board on an opposite side of the second region; and
a connector frame removably attached to the circuit board and comprising:
an elongated base extending along a longitudinal direction x perpendicular to the mating direction and disposed on the top surface of the circuit board behind the first and second regions;
first and second endwalls extending forwardly along the mating direction from respective opposite first and second longitudinal ends of the base, the first and second endwalls at least partially disposed in the respective first and second openings; and
spaced apart first and second middle walls extending forwardly along the mating direction from the base between the first and second endwalls, at least one of the first and second middle walls disposed in the third region, wherein:
the circuit board extends rearwardly along the mating direction beyond the base,
the circuit board extends sidewardly along the longitudinal direction beyond the first and second endwalls; and
when the connector mates with a mating connector, the first and second regions of the circuit board are inserted in the mating connector and each contact pad in the pluralities of first and second contact pads makes contact with a corresponding contact of the mating connector.

2. The elongated electrical connector of claim 1, wherein the pluralities of first and second contact pads are integrally formed by a photolithography process.

3. The elongated electrical connector of claim 1, wherein the pluralities of first and second contact pads are integrally formed by a printing process.

4. The elongated electrical connector of claim 1, wherein each of the first and second middle walls is disposed in the third region of the circuit board.

5. The elongated electrical connector of claim 1, wherein each of the first and second middle walls is disposed in the third region of the circuit board, and the third region defines a third opening at the front edge of the circuit board between the first and second middle walls.

6. The elongated electrical connector of claim 1, wherein the circuit board further comprises a plurality of third contact pads integrally formed in a fourth region on the top surface and near the front edge of the circuit board, the second region disposed between the third and fourth regions, the fourth and second regions defining a fifth region therebetween on the top surface having no contact pads therein, and wherein the first middle wall is disposed in the third region of the circuit board and the second middle wall is disposed in the fifth region of the circuit board, and wherein the third region defines a third opening at the front edge of the circuit board adjacent to the first middle wall.
